(19) United States
(12) Patent Application Publication
(10) Pub. No.: US 2020/0178396 A1
(43) Pub. Date: Jun. 4, 2020

(54) METHOD FOR FORMING CIRCUIT PATTERN ON SURFACE OF THREE-DIMENSIONAL STRUCTURE

(71) Applicant: MDM Inc., Daegu (KR)

(72) Inventor: Ku Yong Kim, Yangsan-si (KR)

(21) Appl. No.: 16/697,186

(22) Filed: Nov. 27, 2019

(30) Foreign Application Priority Data
Dec. 4, 2018 (KR) 10-2018-0154629

(51) Int. Cl. H05K 3/14; H05K 3/46

(52) U.S. Cl. CPC H05K 3/143; H05K 2203/1105; H05K 2203/1366; H05K 3/4644

(57) ABSTRACT

A method for forming a circuit pattern on a surface of a 3D structure includes: forming a first insulation layer on the surface of the 3D structure; forming a conductive pattern on the first insulation layer; forming a second insulation layer on the conductive pattern except for a circuit element mounting region; and mounting one or more circuit elements on the circuit element mounting region.

### CROSS-REFERENCE TO RELATED APPLICATIONS

This application is based on and claims priority under 35 U.S.C. § 119 to Korean Patent Application No. 10-2018-0154629 filed on Dec. 4, 2018 in the Korean Intellectual Property Office, the disclosure of which is herein incorporated by reference in its entirety.

### BACKGROUND

### 1. Field

The present disclosure relates to a method for forming an electronic circuit pattern, and more particularly, to a method for forming a circuit pattern, which can directly form a circuit pattern on a surface of a three-dimensional (3D) structure having a curve formed on the surface.

### 2. Description of the Related Art

It is common that an electronic circuit provided in an electronic device includes a printed circuit board (PCB) and a circuit element mounted thereon. For example, referring to FIG. 1, circuit elements 100 such as a semiconductor, a capacitor, a resistor, or the like are mounted on a PCB 3, and then the PCB 3 is fixedly installed on a structure 1 of an electronic device (for example, a home appliance, a computer, a mobile communication device, a car, or the like). In this case, if the surface of the structure 1 is not flat, it is common that the PCB 3 is installed horizontally by standing a support 2 on the structure 1 and securing the PCB 3 onto the support 2.

In such related-art technology, the structure 1 is typically formed with a material having high thermal conductivity, like an aluminum case. It is effective to install the PCB 3 as close as possible to the surface of the structure 1 in order to diffuse heat generated from the circuit elements 100 or the PCB 3. However, since the PCB 3 is installed above the structure 1, spaced apart therefrom as shown in the drawing, it is not easy to effectively diffuse heat of the circuit elements 100. In addition, since the PCB 3 is installed above the surface of the structure 1, spaced apart therefrom by a predetermined distance, the electronic device requires as much space as that, which may make it difficult to miniaturize the device.

### SUMMARY

The present disclosure has been developed in order to solve the above-described problems, and an object of the present disclosure is to provide a method for forming a circuit pattern, which directly forms a circuit pattern on a 3D structure, thereby effectively diffusing heat generated from a circuit element through the structure having high thermal conductivity, and removes an unnecessary space caused by installation of a PCB and reduces a volume of an electronic device, thereby achieving miniaturization of the device.

To achieve the above-described object, a method for forming a circuit pattern on a surface of a 3D structure includes: forming a first insulation layer on the surface of the 3D structure; forming a conductive pattern on the first insulation layer; forming a second insulation layer on the conductive pattern except for a circuit element mounting region; and mounting one or more circuit elements on the circuit element mounting region.

According to an embodiment of the present disclosure, since an insulation layer and a circuit pattern can be directly formed on a 3D structure, and a circuit element can be directly mounted thereon, heat generated from the circuit element can be effectively diffused through the structure, and an unnecessary space caused by installation of a PCB is removed, such that miniaturization of a device can be achieved.

### BRIEF DESCRIPTION OF THE DRAWINGS

The above and/or other aspects of the present disclosure will be more apparent by describing certain exemplary embodiments of the present disclosure with reference to the accompanying drawings, in which: FIG. 1 is a view illustrating a related-art configuration in which an electronic circuit is installed above a 3D structure;

FIGS. 2A and 2B are views illustrating examples of a circuit pattern and a circuit element which are mounted on a 3D structure according to an embodiment of the present disclosure;

FIG. 3 is a flowchart illustrating a method for forming a circuit pattern on a 3D structure according to an embodiment; and FIGS. 4A, 4B, 4C, and 4D and FIGS. 5A, 5B, and 5C are views illustrating respective steps for forming a circuit pattern according to an embodiment.

### DETAILED DESCRIPTION OF EMBODIMENTS

Exemplary embodiments will now be described more fully with reference to the accompanying drawings to clarify aspects, features and advantages of the present disclosure. The exemplary embodiments may, however, be embodied in many different forms and should not be construed as limited to the exemplary embodiments set forth herein. Rather, the exemplary embodiments are provided so that this disclosure will be thorough and complete, and will fully convey the scope of the application to those of ordinary skill in the art. In the drawings, dimensions of elements such as length, thickness, wideness, or the like are exaggerated for easy understanding of technical features.

As used herein, the singular forms are intended to include the plural forms as well, unless the context clearly indicates otherwise. It will be further understood that the terms “comprise” and/or “comprising,” when used in this specification, do not preclude the presence or addition of one or more other components.

Hereinafter, exemplary embodiments will be described in greater detail with reference to the accompanying drawings. The matters defined in the description, such as detailed construction and elements, are provided to assist in a comprehensive understanding of the exemplary embodiments. However, it is apparent that the exemplary embodiments can be carried out by those of ordinary skill in the art without those specifically defined matters. In the description of the exemplary embodiment, certain detailed explanations of related art are omitted when it is deemed that they may unnecessarily obscure the essence of the inventive concept.

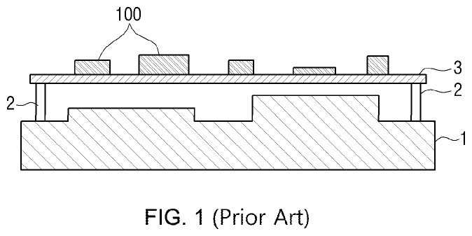

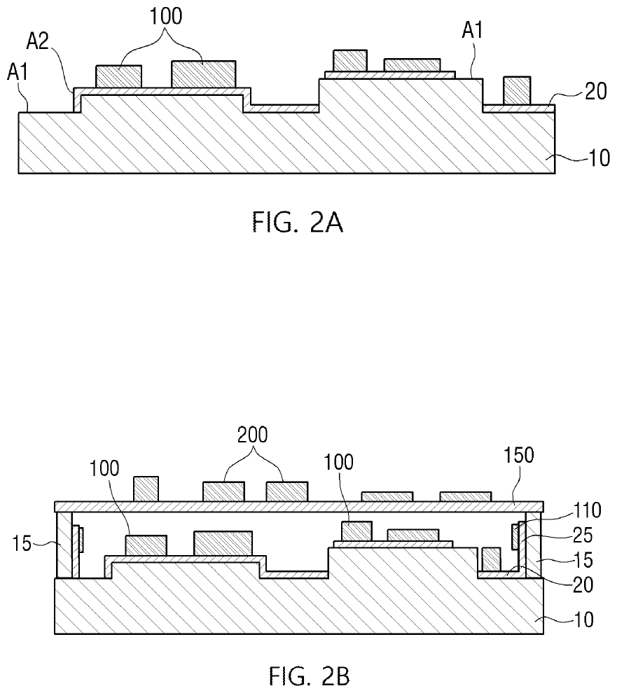

FIGS. 2A and 2B are views illustrating examples of a circuit pattern and a circuit element which are mounted on a 3D structure according to an embodiment of the present disclosure.

Referring to FIG. 2A, a circuit pattern according to an embodiment of the present disclosure is directly formed on a 3D structure 10 and circuit elements are mounted thereon. In the present disclosure, the 3D structure 10 may be a certain structure that forms a part of a certain electronic device or an electronic component. For example, the 3D structure 10 may be a part of an inner surface of a case of a battery module, a heat sink, various home appliances or electronic products, or a part of an outer surface or an inner surface of a case of a component or a module disposed in an electronic product. That is, the 3D structure 10 is not a structure that is originally intended to have a circuit pattern or a circuit element mounted thereon (that is, a circuit board), but a structure that is manufactured for other purposes, not for the purpose of a circuit board, like a case of an electronic device or a module (that is, a case protecting inner components and forming an exterior). Typically, the case of such a device or module may be formed with a material having electrical conductivity and/or thermal conductivity, such as aluminum, and has a 3D shape including a curved surface or a stepped portion according to a purpose or function of the device or component. According to an embodiment of the present disclosure, a circuit pattern can be formed on such a 3D structure which is a part of an outer surface or an inner surface of a case of a device or component.

In an embodiment, an insulation layer 20 may be formed on a region of the surface of the 3D structure 10 where a circuit pattern is to be formed, and a circuit pattern (not shown) may be formed on the insulation layer 20 and then a circuit element 100 may be mounted when necessary. The insulation layer 20 and the circuit pattern may not be formed on some region of the surface of the 3D structure 10 (for example, regions indicated by “A1”), and the circuit pattern may be formed on a stepped portion (for example, a side surface indicated by “A2”) of the 3D structure 10, and a circuit element may be mounted on the stepped portion when necessary. That is, according to the present disclosure, all or some regions of the surface of the 3D structure 10 may be used as a circuit board, regardless of whether the 3D structure 10 has a curved surface or a stepped portion.

FIG. 2B is a view illustrating another exemplary configuration in which a circuit pattern is formed on the 3D structure 10 according to the present disclosure. In this embodiment, after a circuit pattern is formed on the 3D structure 10 and the circuit element 100 is mounted thereon as shown in FIG. 2A, a substrate 150 such as a PCB and a circuit element 200 mounted on the substrate 150 are additionally installed on the 3D structure 10. That is, one or more substrates are additionally stacked on the 3D structure 10 when necessary, such that a degree of integration of the circuit can be enhanced.

In this case, a support pole 15 may be extended from an upper surface of the structure 10, and the substrate 150 is coupled to an upper end of the support pole 15, thereby being disposed above the structure 10. In an embodiment, a circuit pattern according to the present disclosure may also be formed on the support pole 15, and various circuit elements 110 such as a temperature sensor, a humidity sensor, a light sensor, or the like may be mounted thereon when necessary.

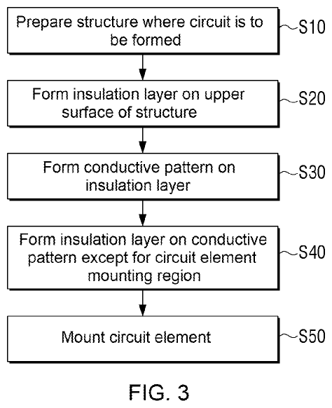

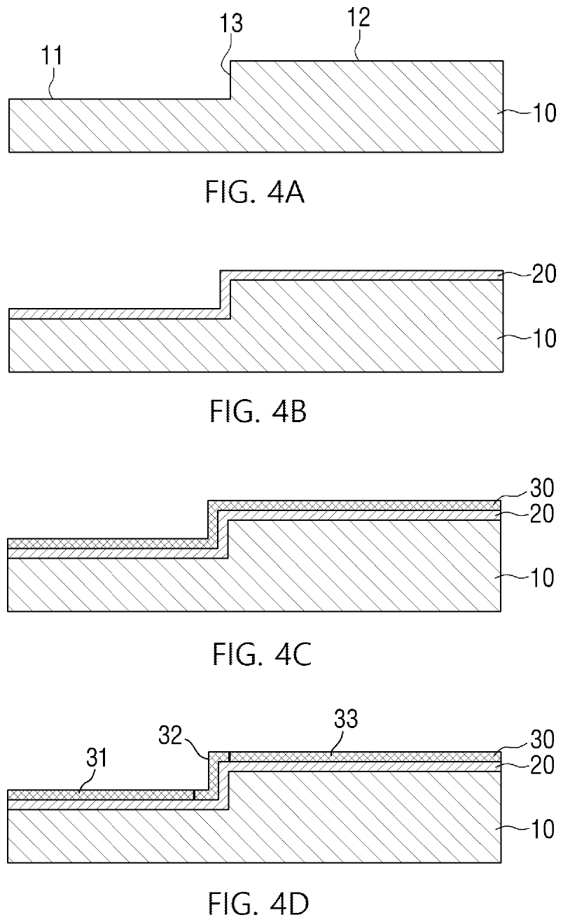

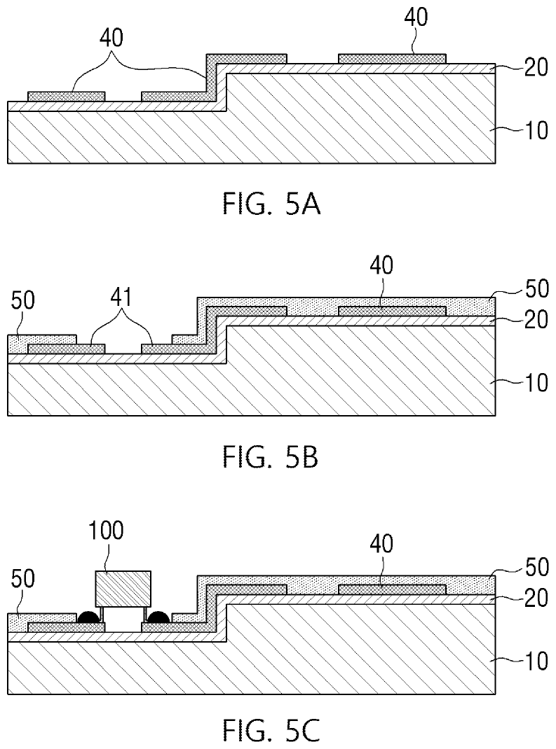

Hereinafter, a method for forming a circuit pattern on a 3D structure will be described with reference to FIGS. 3 to 5C.

FIG. 3 is a flowchart of an exemplary method for forming a circuit pattern on a 3D structure, and FIGS. 4A, 4B, 4C, and 4D and FIGS. 5A, 5B, and 5C are views illustrating respective steps for forming the circuit pattern on the 3D structure.

At step S10, a 3D structure 10 is prepared to have a circuit pattern formed thereon. The 3D structure 10 may be a part of an inner surface of a case of a home appliance or an electronic device, or a part of an outer surface or an inner surface of an electronic component or a module such as a battery module, a heat sink, or the like in a product or a device, and may include a curved surface or a curved region. For convenience of explanation, FIG. 4A illustrates the 3D structure 10 including flat portions 11, 12 which are different in height, and a stepped portion 13 therebetween.

Referring to step S20 of FIG. 3 and FIG. 4B, an insulation layer is formed on an upper surface of the 3D structure 10. In general, the 3D structure 10 may be formed with a metallic material having electrical conductivity, such as aluminum or copper, and the insulation layer 20 is formed thereon to insulate from a circuit pattern.

In an embodiment, at step S20, insulating ink may be coated over the upper surface of the 3D structure 10 by one of screening, spray coating, and solution immersion, or a combination of two or more of the above-mentioned methods. The insulating ink may use, for example, photo solder resist (PSR) ink, but is not limited thereto and a certain insulating liquid or an insulating material in a paste form, which are well known in the related-art, may be used.

The screening method includes a certain screening method, such as silk screening, paste screening, or the like. The spray coating is a method of spraying insulating ink to a region of the surface of the 3D structure 10 where a circuit pattern is to be formed, by using a spray gun. The solution immersion method is a method of immersing the surface of the 3D structure 10 in insulating ink contained in a container.

The method may further include a step of drying (curing) according to a type of insulating ink or paste, after forming the insulation layer 20 by coating the 3D structure with the insulating ink or paste. For example, when PSR insulating ink is used, a process of exposing the insulation layer 20 to ultraviolet rays and then drying in hot air for a predetermined time may be added. Such an insulation layer coating method is well known in the related-art, and thus a detailed description thereof is omitted.

In an alternative embodiment, the insulation layer may be formed by attaching an insulating sheet to the surface of the 3D structure 10. For example, when the insulation layer 20 should be formed on the stepped portion of the 3D structure 10, for example, the insulation layer 20 may be uniformly formed on the stepped portion by using the insulation sheet.

Next, referring to step S30 of FIG. 3 and FIGS. 4C and 5A, a conductive circuit pattern 40 is formed on the insulation layer 20. To achieve this, a mask 30 perforated in the shape of the conductive pattern may be attached to the insulation layer 20 as shown in FIG. 4C, and then, by coating conductive ink over the mask 30 according to the shape of the conductive pattern by one of drawing, spray coating, and screening or a combination of two or more of these methods, the circuit pattern 40 may be formed as shown in FIG. 5A.

In an embodiment, the mask 30 may be a certain film such as a metallic film or a polymer resin film. The mask 30 may already be bent or curved to have the same 3D shape as the 3D surface of the surface of the 3D structure 10 that is to be masked. In addition, the mask 30 may already be perforated according to the shape of the circuit pattern to be formed on the 3D structure 10, and, at step S30, the mask 30 is attached to the insulation layer 20 of the 3D structure. The mask 30 may not be required to be attached to the entire surface of the 3D structure 10 or the insulation layer 20, and the mask 30 may be attached only to a region of the surface of the 3D structure 10 where the circuit pattern is to be formed.

FIG. 4D is a view illustrating an alternative embodiment of the mask 30. In this embodiment, the mask 30 includes a plurality of sub masks 31, 32, 33 to cover different regions of the surface of the 3D structure 10, respectively. For example, the plurality of sub masks may include a flat sub mask to cover a flat region of the 3D structure 10, and a 3D sub mask to cover a stepped portion or a curved portion. In the illustrated embodiment, the first and third masks 31, 33 may be the flat sub masks to cover the flat portions of the surface of the 3D structure, and the second sub mask 32 may be the 3D sub mask which is bent or curved to have the same 3D shape as the 3D surface of the 3D structure.

Ends of the neighboring sub masks may be in close contact with each other, or may have regions overlapping each other, or may be spaced apart from each other.

When the mask is divided into the plurality of sub masks to separately cover the flat portions and the stepped portions of the surface of the 3D structure, the mask 30 can be attached to the insulation layer 20 more easily than when one mask is attached to cover the entire surface of the 3D structure.

After the mask 30 is attached to the insulation layer 20 as described above, conductive ink may be coated according to the shape of the conductive pattern of the mask 30, and the circuit pattern 40 may be formed by removing the mask 30 as shown in FIG. 5A.

In an embodiment, the conductive circuit pattern 40 may be formed by coating with conductive ink in at least one method of drawing, spray coating, and screening.

In the present disclosure, the conductive ink includes conductive paste ink having relatively high viscosity, and conductive nano ink having relatively low viscosity. The conductive paste ink may be manufactured by mixing metallic powder (for example, silver powder) of hundreds of nano meters to a few micro meters with a polymer resin solution, various additives, and a functional solution, and may be used for printing in a screening method. The conductive nano ink may be a mixture of metal nano particles of a few nanometers to hundreds of nanometers with a dispersing agent and various additives, and may be used for various printing methods such as drawing or spray coating as well as screening.

In an embodiment of the present disclosure, certain conductive ink such as paste ink or nano ink may be used as the conductive ink. However, when nano ink is used, calcination at low temperature is possible as a diameter of a nano particle is smaller. Therefore, when the 3D structure 10 is a part of an already manufactured electronic component or module, and it is important to prevent thermal damage of the electronic component or module, it may be preferable to use conductive nano ink formed of nano particles of a few micro meters to tens of micro meters which can be calcined at relatively low temperature. Alternatively, the circuit pattern 40 may be formed in a drawing method by using a conductive ink pen that does not require separate heat calcination.

In an embodiment, when the conductive circuit pattern 40 is formed on the stepped portion 13 or an inclined surface of the curved portion of the 3D structure 10, various combinations of types of conductive ink and/or circuit pattern printing methods may be used. When ink of low viscosity is used for the stepped portion or the inclined surface, it is not easy to uniformly coat the surface of the stepped portion or inclined surface with ink. Therefore, it may be preferable to use nano ink of relatively high viscosity or conductive paste. In addition, in this case, a combination of drawing, spraying, and screening may be used. For example, a circuit pattern may be formed on the stepped portion or inclined surface by using a drawing ink pen, first, and then conductive ink may be coated over the circuit pattern by spraying or screening. In another example, the circuit pattern 40 may be formed by spraying or screening and then conductive ink may be additionally coated over the circuit pattern 40 by drawing.

The method may further include a step of drying the conductive ink after forming the circuit pattern in at least one of spray coating and screening. The step of drying may be performed with the mask 30 being attached as it is after the conductive ink is coated, or may be performed after the mask 30 is removed after the conductive ink is coated.

As a method for drying the conductive ink, drying at high temperature, drying by light reaction, and heat drying may be used. Different drying methods may be performed according to types of the used conductive ink. For example, when drawing is performed along the circuit pattern with a conductive ink pen, the circuit pattern may be formed by drying at high temperature, or, when the conductive ink includes a photo-initiator which reacts to ultraviolet rays, the conductive ink may be dried by radiating ultraviolet rays.

In addition, in the case of normal conductive ink, the conductive ink may be dried by using hot air, radiating light (for example, infrared rays or near infrared rays), or heating by using a convection oven. In this case, when the 3D structure 10 is a part of an already manufactured electronic component or module, it is preferable to dry the conductive ink at as low temperature as possible in order to prevent a damage to the component. For example, when the conductive ink is dried by heating, the conductive ink may be dried at 150° C. or lower, preferably, 100° C. or lower, for a few minutes to several tens of minutes.

After the conductive circuit pattern 40 is formed on the insulation layer 20 as described above, an insulation layer 50 may be formed on the conductive pattern 40 except for a circuit element mounting region 41 as shown in step S40 of FIG. 3 and FIG. 5B. Hereinafter, the insulation layer 50 may be referred to as the “second insulation layer” to be distinguished from the insulation layer 20 (hereinafter, referred to as the “first insulation layer”) formed directly on the 3D structure 10.

The second insulation layer 50 may be formed to cover the entirety of the first insulation layer 20, but the second insulation layer 50 may be formed only to cover the circuit pattern 40 since the main purpose of forming the second insulation layer 50 is to protect the circuit pattern 40. In addition, when the circuit element 100 should be mounted on the circuit pattern 40, the second insulation layer 50 may be formed on a region except for a circuit pattern mounting region 41 as shown in FIG. 5B.

An exemplary method for forming the second insulation layer 50 may include attaching a mask (not shown) perforated in an insulation layer pattern shape to the circuit pattern 40, and then coating insulating ink over the mask according to the insulation layer pattern shape by drawing, screening, or spray coating.

The mask used for forming the insulation layer 50 will be referred to as the “second mask” to be distinguished from the mask 30 (hereinafter, referred to as the “first mask”) used for forming the circuit pattern 40.

The second mask may have the same or similar material as or to that of the first mask 30, and may be, for example, a metallic film or a polymer resin film. The second mask may be a single mask for covering the entirety of the circuit pattern 40, or may include a plurality of sub masks to cover different regions, respectively. When the second mask includes the plurality of sub masks, the plurality of sub masks may include flat sub masks to cover flat regions of the 3D structure 10 and 3D sub masks to cover a stepped portion or a curved portion of the 3D structure, similarly to the first mask 30 of FIG. 4D.

The insulating ink may be the same or similar insulating ink as or to that used for the first insulation layer 20. For example, the insulating ink may use PSR ink, but is not limited thereto, and may use a certain insulating liquid or an insulating material of a paste type, which is well known in the related art. In addition, the method may further include a step of drying (curing) the insulation layer 50 by exposing to ultraviolet rays or heating according to a type of the insulating ink after forming the second insulation layer 50.

After the second insulation layer 50 is formed, the circuit elements 100 are mounted on one or more circuit element mounting regions as shown in step S50 and FIG. 5C. In an embodiment, the circuit element 100 may be mounted by welding, or step S550 may be omitted according to a specific embodiment.

When the circuit pattern is formed on the 3D structure 10 according the present disclosure as described above, the following technical effects can be obtained.

First, according to the present disclosure, a circuit pattern can be formed and a circuit element can be mounted on a 3D surface of an already manufactured electronic component or module in a comparatively simple method. A lithography method including a light exposure process and an etching process may be used as a normal processing method for forming an insulation layer or a circuit pattern on a substrate such as a PCB, but this processing method is complicated and is not easy to apply to a surface of an already manufactured component or module. However, in the present disclosure, insulating ink and conductive ink may be printed by drawing, spraying or screening, and may be dried (cured) at room temperature or relatively low temperature, and also, a metallic or resin film is attached and then is removed without a separate mask layer forming process. Therefore, a circuit pattern can be formed rapidly and simply without a damage to a circuit or element of the component or module.

Second, in the present disclosure, a stepped portion or an inclined surface of a 3D structure can be used as a circuit pattern region. In a related-art method, a circuit pattern is formed only on a flat substrate and a circuit element is attached. However, in the present disclosure, a stepped portion or an inclined surface of a 3D structure can be used, and in particular, a circuit pattern can be formed on the support pole 15 as shown in FIG. 2B, and circuit elements such as various sensors can be installed. Therefore, the entire surface of the 3D structure can be used as a circuit pattern forming region, such that a degree of integration of the circuit can be enhanced.

Third, since the circuit pattern is directly formed on the surface of the 3D structure as described above, heat diffusion efficiency can be enhanced and miniaturization is possible. When the insulation layer and the circuit pattern are formed according to an embodiment of the present disclosure, the insulation layer and the circuit pattern may be formed to have thickness within tens of micrometers (for example, 30-50 micrometers), and accordingly, heat generated from the circuit element or circuit pattern can be effectively diffused through the surface of the 3D structure. In addition, an unnecessary space caused by installation of a PCB is removed, such that miniaturization of a device can be achieved.

While the invention has been shown and described with reference to certain preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present disclosure.

What is claimed is:

1. A method for forming a circuit pattern on a surface of a 3D structure, the method comprising:
forming a first insulation layer on the surface of the 3D structure;
forming a conductive pattern on the first insulation layer; and
forming a second insulation layer on the conductive pattern except for one or more circuit element mounting regions.

2. The method of claim 1, further comprising mounting a circuit element on the circuit element mounting region.

3. The method of claim 1, wherein the forming the first insulation layer comprises forming the first insulation layer by coating an insulating ink over the surface of the 3D structure by screening, spray coating, or solution immersion, and curing the insulating ink, or by attaching an insulation sheet to the surface of the 3D structure.

4. The method of claim 3, wherein the forming the conductive pattern comprises:
attaching a first mask perforated in a shape of the conductive pattern onto the first insulation layer; and
coating a conductive ink over the first mask according to the shape of the conductive pattern by drawing, spray coating, or screening.

5. The method of claim 4, further comprising drying at a temperature of 150° C. or lower after coating the conductive ink.

6. The method of claim 4, wherein the first mask is a metallic film or a polymer resin film.

7. The method of claim 6, wherein the first mask comprises a plurality of sub masks to cover different regions of the surface of the 3D structure, respectively, and
wherein the plurality of sub masks comprise one or more flat sub masks to cover flat regions of the 3D structure, and one or more 3D sub masks to cover stepped portions or curved portions of the 3D structure.

8. The method of claim 4, wherein the forming the second insulation layer comprises:
attaching a second mask perforated in a shape of an insulation layer pattern onto the conductive pattern; and
coating an insulating ink over the second mask in the shape of the insulation layer pattern by drawing, screening, or spray coating, and curing the insulating ink.

9. The method of claim 8, wherein the second mask is a metallic film or a polymer resin film.

10. The method of claim 9, wherein the second mask comprises a plurality of sub masks to cover different regions of the surface of the 3D structure, respectively, and
wherein the plurality of sub masks comprise one or more flat sub masks to cover flat regions of the 3D structure, and one or more 3D sub masks to cover stepped portions or curved portions of the 3D structure.
